(19) United States
(12) Patent Application Publication
(10) Pub. No.: US 2019/0035684 A1
(43) Pub. Date: Jan. 31, 2019

(54) METHOD FOR MANUFACTURING SILICON CARBIDE SEMICONDUCTOR DEVICE

(71) Applicant: DENSO CORPORATION, Kariya-city, Aichi-pref. (JP)

(72) Inventors: Masatake NAGAYA, Kariya-city (JP); Jun KAWAI, Kariya-city (JP); Yosuke TOMITA, Kariya-city (JP)

(21) Appl. No.: 16/082,570

(22) PCT Filed: May 11, 2017
(86) PCT No.: PCT/JP2017/017873

§ 371 Date: Sep. 6, 2018

(30) Foreign Application Priority Data
Jun. 22, 2016 (JP) 2016-123898

(51) Int. Cl. H01L 21/78; H01L 29/16; H01L 23/544

(52) U.S. Cl. CPC H01L 21/78; H01L 2223/54426; H01L 23/544; H01L 29/1608

(57) ABSTRACT

In a case where a back surface of an SiC semiconductor wafer, which is provided by a C surface, is covered with a back surface electrode and a scribe line cannot be confirmed, a reference line is formed before dicing. As a result, even when a processing upper surface from which dicing is carried out is a C surface, the dicing can be performed by estimating a scribe line with reference to the reference line. Accordingly, even if the semiconductor wafer is cut at a higher speed than that in the conventional art, a high-quality SiC semiconductor device with less chipping can be manufactured. A blade abrasion can be reduced, and costs can be also reduced.

### CROSS REFERENCE TO RELATED APPLICATION

This application is based on Japanese Patent Application No. 2016-123898 filed on Jun. 22, 2016, the disclosure of which is incorporated herein by reference.

### TECHNICAL FIELD

The present disclosure relates to a method for manufacturing silicon carbide (hereinafter referred to as SiC) semiconductor devices by dividing a silicon carbide semiconductor wafer formed with vertical semiconductor elements into chips.

### BACKGROUND ART

Conventionally, to manufacture an SiC semiconductor device, elements are formed on an SiC semiconductor wafer, and then the SIC semiconductor wafer is divided into chips by dicing with a dicing blade. In such a case, in order to make the element with a lower resistance, the SiC semiconductor wafer is thinned by grinding or the like and then divided into chips. However, since the SiC semiconductor wafer is thinned, a crack called chipping is likely to occur. In particular, an SiC single crystal, which has a hardness close to that of diamond also, has cleavage properties and induces chipping on front and back surfaces and side surfaces of the chip depending on processing conditions. Since the chipping can cause chipping or cracking in the chip due to a stress difference with different materials in a subsequent assembly or the like, it is important to reduce chipping during the dicing.

Patent Literature1 has proposed a method for suppressing an occurrence of chipping when the SiC semiconductor wafer is divided into chips. Specifically, chipping is reduced by setting a rotational direction of the dicing blade in a direction from a C surface toward an Si surface in the SiC semiconductor wafer.

### PRIOR ART LITERATURE

### Patent Literature

Patent Literature 1: JP2014-13812A

### SUMMARY OF INVENTION

However, when the vertical semiconductor element is formed on the SiC semiconductor wafer, a front surface may be provided by the Si surface and a back surface may be provided by the C surface. In such a case, a back surface electrode is formed on the entire back surface, and thus a scribe line along which the dicing is to be performed cannot be recognized. For that reason, there arises a drawback that the SiC semiconductor wafer cannot be precisely divided into chips.

In view of the foregoing, an object of the present disclosure is to provide a method for manufacturing an SiC semiconductor device which is capable of accurately dividing an SiC semiconductor wafer into chips even when a C surface of the SiC semiconductor wafer is covered with an electrode.

A method for manufacturing a silicon carbide semiconductor device according to an aspect of the present disclosure includes: preparing a semiconductor wafer that has a front surface provided by an Si surface, and a back surface provided by a C surface and formed with a semiconductor element, and includes a back surface electrode covering at least a portion of the back surface where the semiconductor element is formed; forming a reference line along a scribe line from the front surface of the semiconductor wafer; and dividing an effective region into chips by dicing the semiconductor wafer from the back surface with the dicing blade with reference to the reference line, in a state where the back surface electrode has been formed on the semiconductor wafer.

As described above, when the back surface of the SiC semiconductor wafer, which is provided by the C surface, is covered with the back surface electrode and the scribe line cannot be confirmed, the reference line is formed before the dicing. For that reason, even when a processing upper surface from which the dicing is carried out is the C surface, the dicing can be performed by estimating the scribe line with reference to the reference line. As a result, the semiconductor wafer can be accurately divided into the chips.

### BRIEF DESCRIPTION OF DRAWINGS

FIG. 1 is a perspective view showing a state in which a semiconductor wafer according to a first embodiment is cut by a dicing blade to take out chips.

FIG. 2 is a cross-sectional view showing cutting directions and a feeding direction of a dicing blade according to the first embodiment.

FIG. 3A is a front view of the semiconductor wafer before dicing.

FIG. 3B is a front view of the semiconductor wafer formed with reference lines.

FIG. 3C is a rear view of the semiconductor wafer showing a state in which dicing is performed from a back surface of the semiconductor wafer with reference to the reference lines.

FIG. 4 is a front view of the semiconductor wafer showing a state when the reference lines are formed on the semiconductor wafer formed with notches.

FIG. 5 is a diagram showing processing conditions for the dicing.

FIG. 6 is a front view illustrating a workpiece to be diced.

FIG. 7A is a front view of one chip taken out from the workpiece after the dicing.

FIG. 7B is a rear view of one chip taken out from the workpiece after the dicing.

FIG. 8 is a diagram showing results of the dicing.

FIG. 9 is a diagram showing a chipping amount representing a size of chipping formed in the chipping.

FIG. 10 is a diagram showing the results of examining the chipping amount while changing a width of a dicing blade and a feeding speed of the dicing blade in a moving direction.

### DESCRIPTION OF EMBODIMENTS

Hereinafter, embodiments of the present disclosure will be described with reference to the drawings. In the following respective embodiments, parts identical with or equivalent to each other are denoted by the same symbols for description.

### First Embodiment

A method for manufacturing an SiC semiconductor device according to a first embodiment will be described. In manufacturing the SiC semiconductor device, a process of dividing an SiC semiconductor wafer into chips is performed after a process of subjecting the SiC semiconductor wafer to a device manufacturing process. Since the device manufacturing process is similar to a conventional process, the process of dividing the SiC semiconductor wafer into the chips will be described.

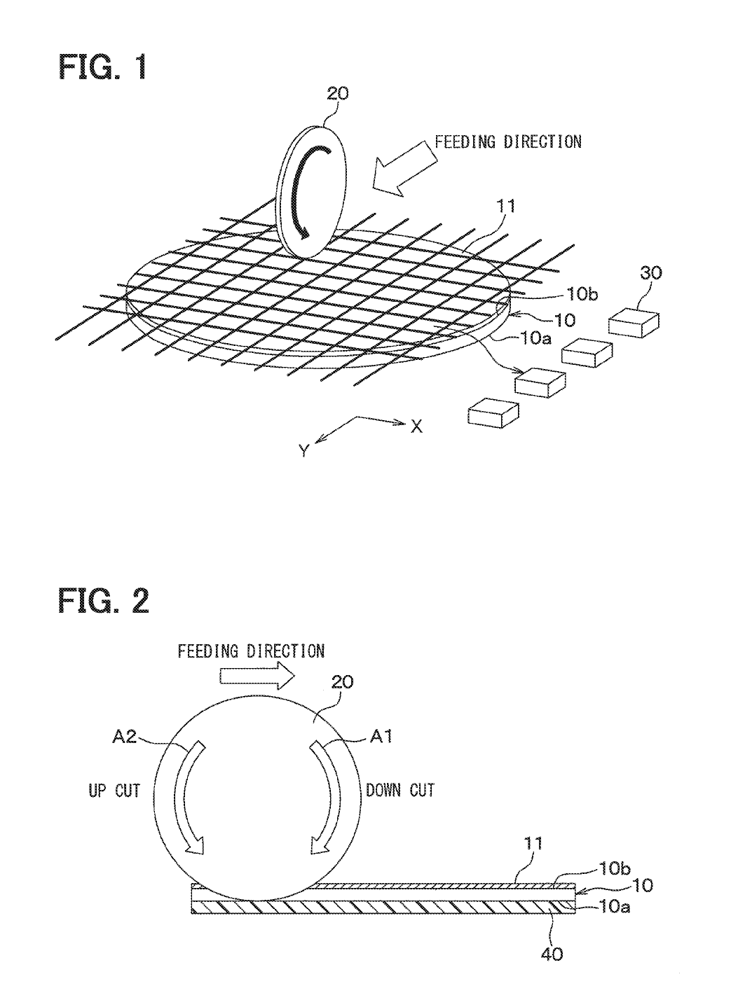

As shown in FIG. 1, an SiC semiconductor wafer 10 which has undergone a device manufacturing process is prepared. In the SiC semiconductor wafer 10, a front surface 10a is provided by an Si surface and a back surface 10b is provided by a C surface. In the SiC semiconductor wafer 10, a vertical semiconductor element, for example, a MOSFET, a Schottky diode, or the like is formed as a device, and the entire back surface 10b is covered with a back surface electrode 11.

The SiC semiconductor wafer 10 on which the vertical semiconductor element is formed as described above is cut by a dicing blade 20 to divide the SiC semiconductor wafer 10 into chips, thereby manufacturing chips 30 of the SiC semiconductor device. In the front surface 10a of the SiC semiconductor wafer 10, a direction along the front surface 10a is referred to as an X direction, and a direction along the front surface 10a and perpendicular to the X direction is referred to as a Y direction. A plane including the X direction and the Y direction is referred to as an XY plane. Specifically, the dicing blade 20 is scanned along the XY-plane to manufacture semiconductor chips with a predetermined size. For example, the SiC semiconductor wafer 10 having a (0001) surface as the front surface 10a and a (000-1) surface as the back surface 10b is used, and dicing is performed in the X-direction and the Y-direction while setting the X-direction in (1-100) direction and the Y-direction in (11-20) direction.

In this case, in order to restrict chipping from occurring in the SiC semiconductor wafer 10, the dicing blade 20 is disposed on the back surface 10b provided by the C surface, and a blade of the dicing blade 20 is inserted in a direction from the back surface 10b toward the front surface 10a to perform dicing. In other words, the dicing blade 20 is disposed adjacent to the back surface 10b, and the blade is inserted in the direction from the C surface toward the Si surface.

As shown in FIG. 2, the dicing by the dicing blade 20 is performed in a state where the SiC semiconductor wafer 10 is held and a dicing tape 40 is attached to the SiC semiconductor wafer 10 so that the chips are not displaced after division. Further, there are two rotational directions of the dicing blade 20. Specifically, in the case where a right direction of a paper surface of FIG. 2 is defined as a traveling direction of the dicing blade 20, there are a down cut in which the blade of the dicing blade 20 moves from top to bottom as indicated by an arrow A1 and an up cut in which the blade of the dicing blade 20 moves from bottom to top as indicated by an arrow A2. The dicing may be performed in any rotational direction. However, as it will be described later, the down cut is preferable in consideration of reductions in a residual stress after dicing and a blade abrasion amount, in addition to a reduction in chipping.

The dicing is performed by the dicing blade 20 from the back surface 10b, which is the C surface. However, the entire back surface 10b is covered with the back surface electrode 11, and hence scribe lines cannot be confirmed.

For that reason, a process for allowing the scribe lines to be confirmed is performed before performing the dicing for diving into chips.

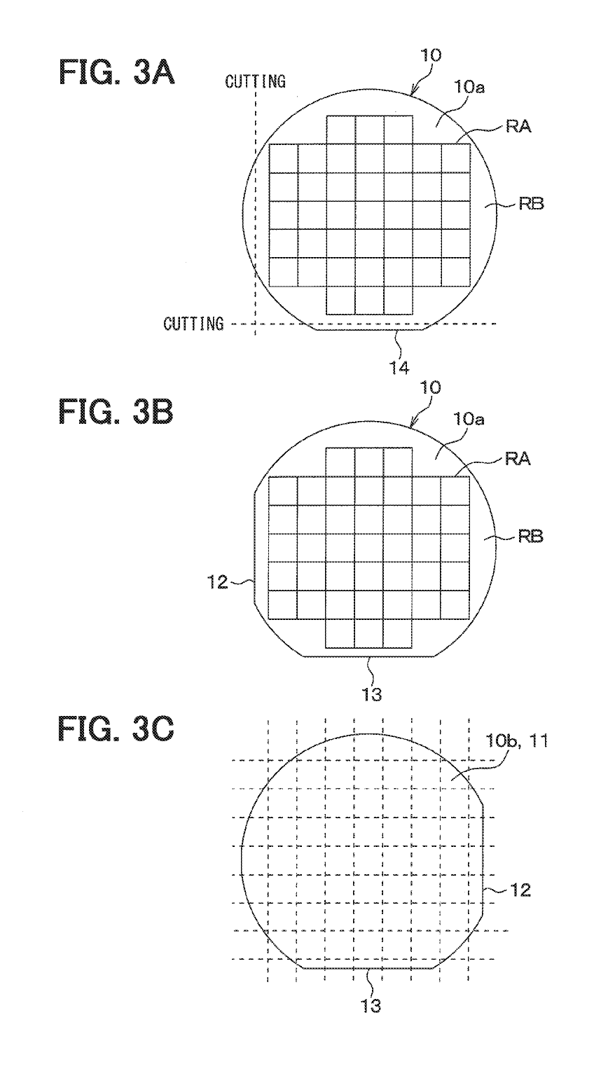

Specifically, as shown in FIG. 3A, the SiC semiconductor wafer 10 in which elements have been formed and the scribe lines have been determined is prepared. Then, as shown in FIG. 3B, dice-cutting is performed from the front surface 10a in accordance with the scribe lines to form reference lines 12 and 13 in the X-direction and the Y-direction, respectively. The reference lines 12 and 13 may be outermost lines of an effective region RA from which chips are taken out. In this example, the reference lines 12 and 13 are formed in an ineffective region RB, which is not to be divided into the chips, and at positions separated from the effective region RA, which is to be divided into the chips, by predetermined distances. The distances from the reference lines 12 and 13 to the effective region RA may be the same as or different from each other. The effective region RA is defined in a region of the SiC semiconductor wafer 10 avoiding arcuate outer edge portions, and the ineffective region RB is defined outside the effective region RA.

The reference lines 12 and 13 are formed in a state where the scribe lines can be confirmed, and provided by dicing the SiC semiconductor wafer 10 from the front surface 10a side. For that reason, in forming the reference lines 12 and 13, the blade of the dicing blade 20 is inserted into the SiC semiconductor wafer 10 in the direction from the Si surface toward the C surface, resulting in a risk that chipping may occur. Therefore, although the reference lines 12 and 13 may be set at the outermost lines of the effective region RA, it is preferable to form the reference lines 12 and 13 in the ineffective region RB in view of occurrence of chipping. As described above, when the reference lines 12 and 13 are provided at the positions separated from the effective region RA by the predetermined distances, even if chipping occurs at the time of forming the reference lines 12 and 13, it is less likely that end faces of the finally formed chips will have chipping.

In this case, the reference lines 12 and 13, that is, two lines respectively parallel to the X-direction and Y-direction orthogonal to each other are provided. However, as shown in FIG. 3A, in a case where the SiC semiconductor wafer 10 is formed with an orientation flat 14, the orientation flat 14 may be used as one of the reference lines 12 and 13. In the case of the present embodiment, the orientation flat 14 can be used as the reference line 13. In other words, if the orientation flat 14 is formed in one of the X-direction and the Y-direction, it can be used as one of the reference line 12 and the reference line 13, the one corresponding to the direction of the orientation flat 14.

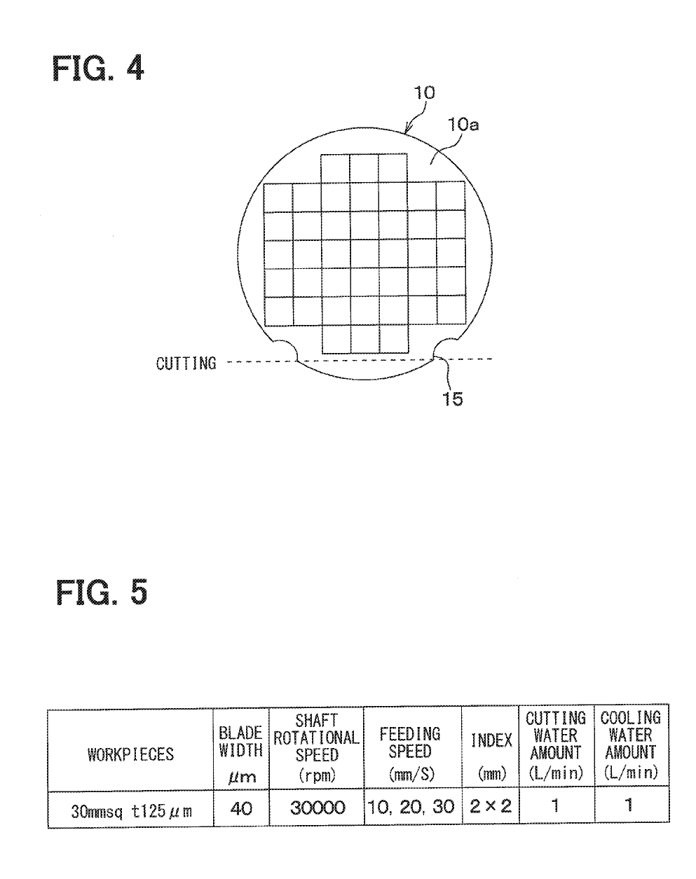

As shown in FIG. 4, the SiC semiconductor wafer 10 may be formed with notches 15, instead of the orientation flat 14. In this case, as indicated by a broken line in FIG. 4, the reference line 12, 13 may be formed along the X-direction or the Y-direction at a position where the notches 15 are formed.

After the reference lines 12 and 13 have thus been formed, the dicing tape 40 is attached to the front surface 10a of the SiC semiconductor wafer 10 as described above, and dicing is then performed by the dicing blade 20 from the back surface 10b side. In this case, since the reference lines 12 and 13 have been formed on the SiC semiconductor wafer 10, the scribe lines are recognized with reference to the reference lines 12 and 13, and the dicing is performed by scanning the dicing blade 20 in the X-direction and the Y-direction along the scribe lines. Namely, since positions where the reference lines 12, 13 are formed are located at the predetermined distances from the effective region RA, the scribe lines can be estimated with reference to the reference lines 12 and 13. As a result, even if the scribe lines cannot be visually recognized due to the back surface electrode 11, the dicing can be accurately performed along the scribe lines with reference to the reference lines 12 and 13, and the SiC semiconductor wafer 10 can be precisely divided into the chips.

In addition, as described above, the reference lines 12 and 13 are provided in the ineffective region RB, specifically, at the positions separated by the predetermined distances from the effective region RA. For that reason, even if chipping occurs during the forming of the reference lines 12 and 13, a portion where the chipping has occurred can be removed when dicing is performed newly on the scribe lines. Therefore, it is less likely that the chips manufactured will have the chipping.

Next, processing conditions of the dicing will be described.

In the SiC semiconductor wafer 10 to be diced, for the purpose of reducing a resistance of the vertical semiconductor element, that is, reducing an on-resistance, the back surface electrode 11 is formed on the SiC semiconductor wafer 10 after the SiC semiconductor wafer 10 is thinned such as by grinding the back surface 10b. For that reason, a thickness of the SiC semiconductor wafer 10 is set to, for example, 125 μm or less, preferably 100 μm or less. Since the thin SiC semiconductor wafer 10 is diced as described above, a width of the dicing blade 20 (hereinafter referred to as the blade width), and a feeding speed in a traveling direction and a rotation direction of the dicing blade 20 are set in order to suppress an occurrence of chipping.

FIG. 5 is a diagram showing the processing conditions. Multiple workpieces configured by the SiC semiconductor wafer 10 are prepared, and dicing is performed with different conditions for each workpiece.

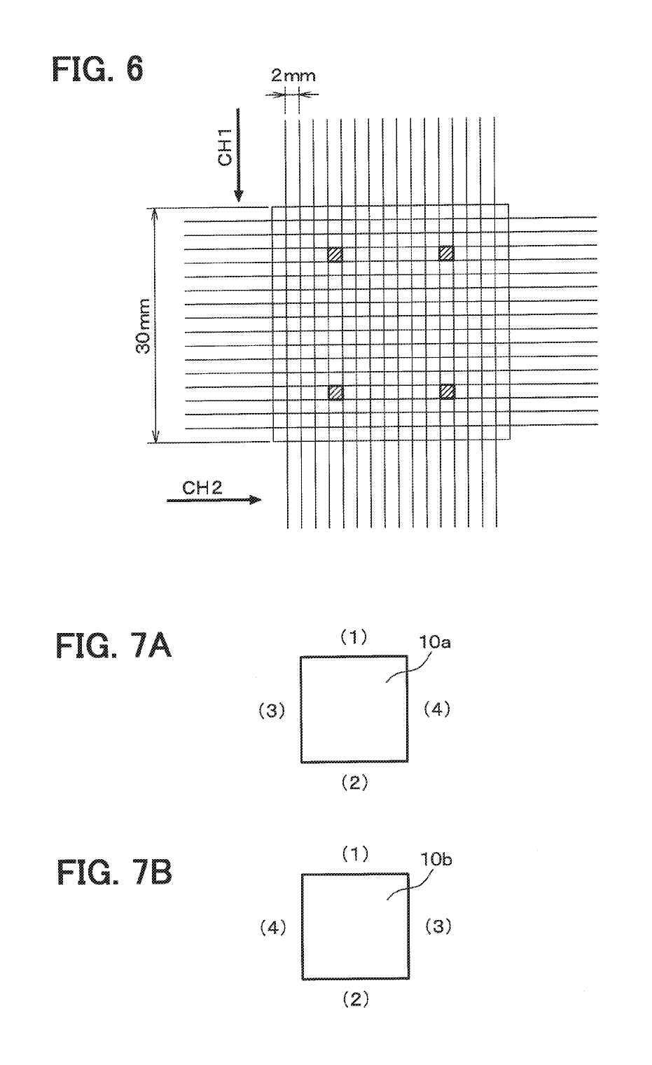

As shown in FIG. 6, each workpiece whose effective region RA is 30 mm square is prepared, and each chip having an Index of 2 mm×2 mm is fabricated. Further, as the direction of the dicing, after the dicing in a direction of CH1 which is a (1-100) direction is performed, the dicing in a direction of CH2 which is an (11-20) direction is performed. However, the order may be reversed or the dicing directions may be alternately changed.

The blade width of the dicing blade 20 is set to 40 μm, and the rotational speed is set to 30000 rpm. Also, the dicing is performed for both directions of up cut and down cut. Further, the dicing is performed by switching the feeding speed of the dicing blade 20 in the traveling direction at three levels of 10, 20, and 30 mm/S. In other words, in the up cut, the dicing is performed for the three workpieces while switching the feeding speed to another. In the down cut, the dicing is performed for the three workpieces while switching the feeding speed to another. Both the amount of water for cutting and the amount of water for cooling, that is, the amount of water supplied to the side of the cutting surface of the dicing blade 20 and the amount of water supplied to both end faces of the dicing blade 20 are set at 1 L/min. The dicing described above is performed for the case where a processing upper surface of the workpiece to be diced is set as the Si surface and the case where the processing upper surface of the workpiece to be diced is set as the C surface.

After the dicing described above has been performed, any four of the divided chips are extracted from each workpiece, as shown by hatching in FIG. 6, and a state of chipping is investigated. In this example, four samples disposed at symmetrical positions around a center of the workpiece are taken as samples.

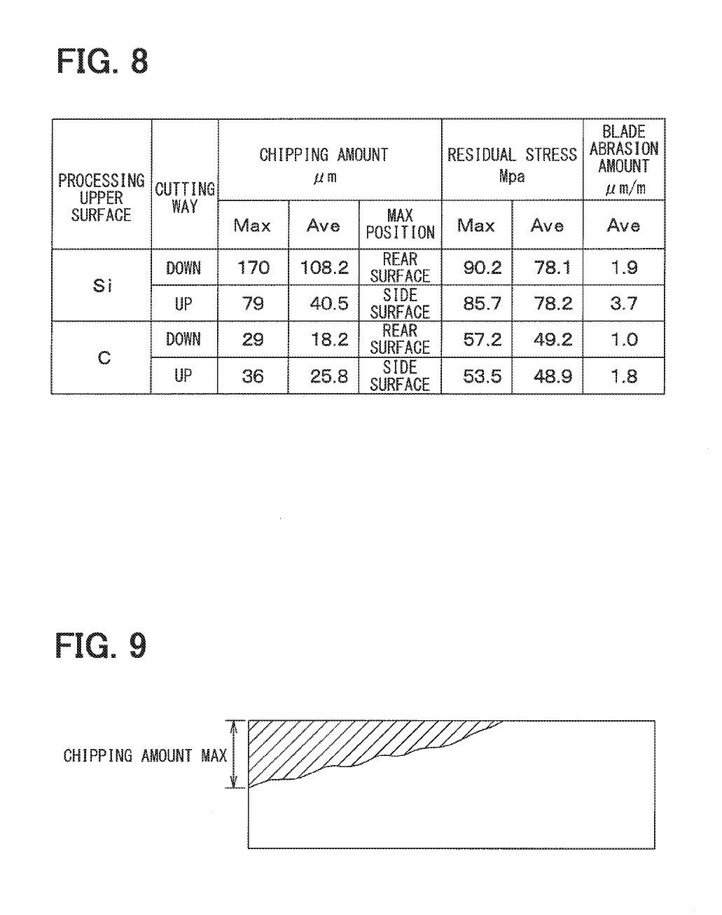

The state of chipping is confirmed on the front surface 10a of the chip as shown in FIG. 7A, on the back surface 10b of the chip as shown in FIG. 7B, and on each of the four cross sections (1) to (4), that is, on twelve positions in total. As a result, results shown in FIG. 8 are obtained. The amount of chipping shown in the figure represents a size of chipping. In the case of chipping whose depth is changed as shown in FIG. 9, a value at which the amount of chipping is maximum is indicated as a chipping amount Max. Although FIG. 9 is not a cross-sectional view, a position of the chipping is hatched. Also, an average value of the chipping amount Max at each of the four sides is denoted as a chipping amount Ave. Further, a position at which the chipping amount Max is obtained is denoted as a Max position.

Furthermore, a residual stress represents a residual stress in a sample after dicing. The residual stress is confirmed by performing a Raman spectroscopic analysis on the sample based on an optical microscope image. With respect to the abrasion amount of the blade, the amount of change of an outer diameter of the dicing blade 20 before and after the dicing is examined.

As a result, as shown in FIG. 8, in the case where the upper surface of a processing surface to be diced is set as the Si surface, when the cutting direction is each of the down cut and the up cut, the chipping amount Max is as large as 170 μm and 79 μm, and the average chipping amount Ave is also as large as 108.2 μm and 40.5 μm. Similarly, in regard to the residual stress, even when the cutting direction is changed, the maximum value Max is 90.2 Mpa and 85.7 Mpa and the average value Ave is as large as 78.1 Mpa and 78.2 Mpa. In regard to the blade abrasion amount, the average value Ave is not so high, that is, 1.9 μm/m in the case of down cut, but the average value Ave is as large as 3.7 μm/m in the case of up cut.

On the contrary, in the case where the upper surface of a processing surface to be diced is set as the C surface, when the cutting direction is each of the down cut and the up cut, the chipping amount Max is as small as 29 μm and 36 μm, and the average chipping amount Ave is also as small as 18.2 μm and 25.8 μm. Similarly, in regard to the residual stress, the maximum value Max is 57.2 Mpa and 53.5 Mpa in any case of the down cut and the up cut and the average value Ave is as small as 49.2 Mpa and 48.9 Mpa. In regard to the blade abrasion amount, the average value Ave is not so high, that is, 1.8 μm/m in the case of up cut, but the average value Ave is as small as 1.0 μm/m in the case of down cut.

It is found based on those experimental results that when the processing upper surface from which the dicing is carried out is set to the C surface, as compared with the case in which the processing upper surface from which the dicing is carried out is set to the Si surface, the chipping amount can be reduced and the residual stress can be also reduced. The blade abrasion amount can also be reduced by setting the processing upper surface from which the dicing is carried out to the C surface, and the blade abrasion amount can be remarkably reduced in particular by setting the cutting direction to the down cut.

In the above experiment, the blade abrasion amount is also confirmed because there is a correlation between the chipping amount and the blade width of the dicing blade 20. In other words, the blade abrasion amount can be reduced with an increase in the blade width. However, since the chipping amount increases with an increase in the blade width, the blade width needs to be set to a certain width or less. Even if the blade width is increased, the chipping amount can be reduced by decreasing the feeding speed of the dicing blade 20 in the traveling direction during the dicing. However, it is preferable to increase the feeding speed from the viewpoint of throughput. For that reason, in order to reduce the abrasion amount of the dicing blade 20 while increasing the feeding speed, there is a need to reduce the abrasion amount based on the cutting direction or the processing upper surface set to any one of the Si surface and the C surface while setting the blade width to a certain width or less.

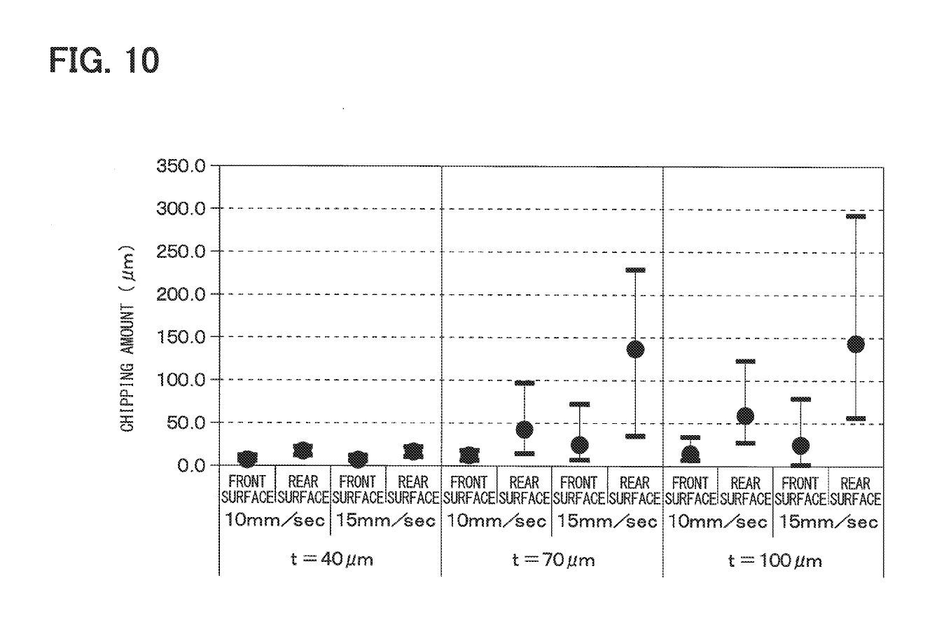

FIG. 10 shows the results when the chipping amount is examined while changing the feeding speed of the dicing blade 20 in the traveling direction, with the use of the dicing blades 20 having blade widths t of 40 μm, 70 μm, and 100 μm. In this example, the C surface of the workpiece formed of the SiC semiconductor wafer 10 is set as the processing upper surface, the workpiece is diced from the C surface side by down cut, and the chipping amount is examined on each of the front surface and the back surface of the workpiece.

As shown in FIG. 10, when the blade width is 40 μm, the chipping amount can be reduced in both of the case where the feeding speed is 10 mm/sec and the case where the feeding speed is 15 mm/sec. On the other hand, in the case where the blade widths are 70 μm and 100 μm, only the chipping amount on the front surface side of the workpiece is reduced when the feeding speed is 10 mm/sec. In other cases, the chipping amount cannot be reduced. In particular, the chipping amount is increased more as the feeding speed is increased more.

Conventionally, the feeding speed of the blade at the time of dicing is generally set to 3 to 5 mm/sec. In such a range of the feeding speed, even if the blade width is increased, the chipping amount can be reduced, but a high throughput cannot be obtained. In order to obtain a high throughput, the feeding speed may be set to, for example, preferably 10 mm/sec or more, and more preferably 15 mm/sec or more. The blade width capable of reducing the chipping amount even at the above feeding speed is preferably set to 40 μm or less. In order to further reduce the abrasion amount of the dicing blade 20, it is preferable to set the cutting direction to down cut.

As described above, when the back surface 10b of an SiC semiconductor wafer 10, which is the C surface, is covered with the back surface electrode 11 and a scribe line cannot be confirmed, the reference lines 12 and 13 are provided before dicing. For that reason, even when a processing upper surface from which the dicing is carried out is provided by a C surface, dicing can be performed by estimating a scribe line with reference to the reference lines 12 and 13. As a result, the semiconductor wafer 10 can be accurately divided into the chips.

Also, in the case where the thickness of the SiC semiconductor wafer 10 is thin, specifically set to be 125 μm or less, chipping tends to occur. However, since dicing can be performed from the C surface side, chipping can be suppressed and the residual stress can be reduced. In particular, when the blade width of the dicing blade 20 is set to 40 μm or less, chipping can be suppressed even if the feeding speed at the time of dicing is increased. Furthermore, when the cutting direction of the dicing is set to down cut, the abrasion amount of the dicing blade 20 can be reduced.

From the viewpoint of the residual stress, the residual stress is the smallest when the upper surface to be diced is set to the C surface and the cutting direction is set to the up cut. For that reason, the residual stress can be reduced by setting the cutting direction to the up cut depending on the pattern configuration of the device and a cutting pitch at which the dicing is performed.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure,

For example, in the embodiment described above, the vertical semiconductor element is exemplified as the semiconductor element formed on the SiC semiconductor wafer 10. However, the above configuration is merely an example of a structure in which the C surface serving as the processing upper surface from which the dicing is carried out is covered with a creeping electrode. In other words, since the same issue as described above occurs at the time of dicing in the structure where the entire C surface is covered with the electrode, even if a semiconductor element is other than the vertical semiconductor element, the above embodiment can also be applied to the semiconductor element to which the same structure is applied. For example, there is a structure in which the back surface electrode is formed so as to fix the C surface to the ground potential.

Although the case in which the entire C surface is covered with the back surface electrode 11 has been described, a structure in which at least a portion where a semiconductor device to be formed as a chip is formed is covered with the back surface electrode 11 which makes it difficult to confirm the scribe lines can be applied to the above embodiment.

Further, in the above-described embodiment, the circular arc portion of a part of the ineffective region RB is linearly cut as to form the reference lines 12 and 13. However, the reference line 12, 13 may be provided by a mark that can also be confirmed from the back surface 10b by dicing from the front surface 10a side. For that reason, even if cutting is not performed so as to remove the circular arc portion of a part of the ineffective region RB, the reference line 12, 13 may be provided by cutting off a part of the ineffective region RB.

Further, formation of the reference lines 12 and 13 can be performed by various processing methods or cutting methods including various dicing methods. For example, the reference lines 12 and 13 can be provided by various processing methods or cutting methods such as breaking in which a break line is engraved and then divided, laser dicing, a dicing blade, or breaking performed after half cutting by laser dicing.

In the case of indicating the crystal orientation, a bar (-) should be originally attached above a desired number. However, because the restricted expression based on electronic applications exists, the bar is attached in front of the desired number in this description.

1. A method for manufacturing a silicon carbide semiconductor device, comprising:
preparing a semiconductor wafer that has a front surface provided by an Si surface, and a back surface provided by a C surface and formed with a semiconductor element, and includes a back surface electrode covering at least a portion of the back surface where the semiconductor element is formed;
forming a reference line along a scribe line from the front surface; and
dividing semiconductor wafer into chips by dicing the semiconductor wafer from the back surface with a dicing blade with reference to the reference line in a state where the back surface electrode has been formed on the semiconductor wafer.

2. The method for manufacturing the silicon carbide semiconductor device according to claim 1, wherein
a region of the semiconductor wafer where the semiconductor element is formed is referred to as an effective region to be divided into chips along the scribe line by the dicing, and a region of the semiconductor wafer outside of the effective region is referred to as an ineffective region, and
in the forming of the reference line, the semiconductor wafer is diced from the front surface in the ineffective region so as to form the reference line at a position distant from the effective region.

3. The method for manufacturing the silicon carbide semiconductor device according to claim 1, wherein
in the dividing into the chips, the dicing blade having a blade width of 40 μm or less is used.

4. The method for manufacturing the silicon carbide semiconductor device according to claim 3, wherein
in the dividing into the chips, a feeding speed of the dicing blade is set to 10 mm/sec or more.

5. The method for manufacturing the silicon carbide semiconductor device according to claim 1, wherein
in the dividing into the chips, the semiconductor wafer is divided into the chips by down-cutting in which a blade of the dicing blade moves from top toward down in a cutting portion of the semiconductor wafer.

6. The method for manufacturing the silicon carbide semiconductor device according to claim 1, wherein
in the preparing of the semiconductor wafer, the semiconductor wafer formed with an orientation flat that is parallel to one direction of the scribe line is prepared,
in the forming of the reference line, the reference line in a direction perpendicular to the orientation flat is formed by the dicing as a first reference line, and
in the dividing into the chips, the orientation flat is used as a second reference line, and the semiconductor wafer is divided into the chips with reference to the first reference line and the second reference line.
